(19) United States
(12) Patent Application Publication
(10) Pub. No.: US 2021/0363659 A1
(43) Pub. Date: Nov. 25, 2021

(54) Seed Crystal, Method for Preparing Monocrystal Silicon by Czochralski Method and Monocrystal Silicon

(71) Applicant: XUZHOU XINJING SEMICONDUCTOR TECHNOLOGY CO., LTD., Xuzhou, Jiangsu (CN)

(72) Inventor: Jiazhen ZHENG, Xuzhou, Jiangsu (CN)

(21) Appl. No.: 16/966,905

(22) PCT Filed: Dec. 20, 2019
(86) PCT No.: PCT/CN2019/126987

§ 371 Date: Aug. 3, 2020

(30) Foreign Application Priority Data
Dec. 25, 2018 (CN) 201811587812.5
Dec. 25, 2018 (CN) 201822196017.5

(51) Int. Cl. C30B 15/36; C30B 29/06; C30B 15/04

(52) U.S. Cl. CPC C30B 15/36; C30B 15/04; C30B 29/06

(57) ABSTRACT

A seed crystal, a method for preparing monocrystal silicon by a seed crystal and a Czochralski method and the monocrystal silicon are disclosed, herein, the seed crystal is provided with a hole, and additives can be stored in the hole.

### CROSS-REFERENCE TO RELATED APPLICATION

The present application claims priority to Chinese patent application, submitted to State Intellectual Property Office of P. R. China on Dec. 25, 2018, with patent application number of 201811587812.5 and application title of “Seed crystal, Method for Preparing Monocrystal Silicon by Czochralski Method and Monocrystal Silicon” and priority to Chinese patent application, submitted to State Intellectual Property Office of P. R. China on Dec. 25, 2018, with patent application number of 201822196017.5 and application title of “Seed crystal”, the disclosure of which are hereby incorporated by reference in their entirety.

### TECHNICAL FIELD

The present disclosure belongs to the field of monocrystal silicon, and particularly, the present disclosure relates to the seed crystal, a method for preparing monocrystal silicon by a Czochralski method and the monocrystal silicon.

### BACKGROUND

In a growth process of a Czochralski monocrystal, various additives need to be added, including the additives such as Ill group dopant, V group dopant, a quartz crucible modifier, a silicide or a nitride and the like. In a traditional single crystal pulling process, the additive and raw material are generally put into a quartz crucible together during the charge preparation. With the development of Recharge Czochralski (RCZ) and Continuous Czochralski (CCZ) technologies, in the process of the Czochralski monocrystal growth, multiple times of feeding are required, and additives, need to be added again during each time of re-charging.

Presently additives are added into silicon melt by means of an external or internal quartz tube, but often because weights of the additive are too light, which make rolling is not good or the additive is stuck to a wall of the quartz tube, so that the additive is not completely added into the silicon melt, which in turn cause a shift of the electrical resistivity of obtained monocrystal silicon, or the quartz crucible modifier or nitrogen atom concentration are incorrect, thereby a production yield is seriously affected. In addition, argon gas needs to be charged and extracted while the internal feeding quartz tube is replaced and used, and then the argon gas is charged and extracted again while a seed crystal is replaced, which results in an increase in production time.

Furthermore, regardless of the use of the external or internal quartz tube to add the various additives, the additive is easily blown away by the argon gas in a furnace. For a down-pumped crystal growth furnace, arcing often occurs near electrode feet of a heater, seriously it will also cause damage to the electrode feet so that feeding is terminated earlier than scheduled.

Therefore, an existing mode of adding the additive in a process of preparing the monocrystal silicon needs to be improved.

### SUMMARY

The present disclosure aims to solve one of technical problems in related technologies at least to some extent. For this reason, a purpose of the present disclosure is to provide a seed crystal, a method for preparing monocrystal silicon by a Czochralski method and the monocrystal silicon, the seed crystal can guarantee that an additive is completely added into molten silicon, not only problems that the additive is stuck to a wall of a quartz tube and the additive is taken away by an argon gas in a furnace so that a product yield is too low are effectively avoided, but also a probability of arcing at electrode feet is reduced for a down-pumped crystal growth furnace, times of charging and extracting the argon gas are reduced at the same time, and production time is saved.

In one aspect of the present disclosure, the present disclosure provides a seed crystal. According to an embodiment of the present disclosure, the seed crystal is provided with a hole, additive can be stored in the hole.

Thus, the seed crystal of the embodiment of the present disclosure is provided with the hole, the additive can be stored in the hole, the seed crystal is immersed in the molten silicon during a process of preparing the monocrystal silicon by the Czochralski method, the additive filled in the hole is mixed with the molten silicon, and then the seed crystal is operated by the Czochralski method to prepare doped monocrystal silicon. Compared with an existing mode of adding the additives by using the external or internal quartz tube, it can be guaranteed that the additive is completely added into the molten silicon by using the seed crystal of the present application, not only the problems that the additive is stuck to the wall of the quartz tube and the additive is taken away by the argon gas in the furnace so that the product yield is too low are effectively avoided, but also the probability of arcing at the electrode feet is reduced for the down-pumped crystal growth furnace, times of charging and extracting the argon gas are reduced at the same time, and the production time is saved. At the same time, the seed crystal of the present application is used, the hole and the seed crystal are integrally formed, herein not only the additive is not easy to fall so as to avoid causing the loss of the additives, but also the additive does not fall in advance and is molten within a specified time, for crystal growth of CCZ and RCZ, growth time can be accurately controlled, and production efficiency is improved.

In addition, the seed crystal according to the above embodiment of the present disclosure can also have the following additional technical features.

Preferably, the hole is filled by using a silicon-series material part. Thus, in a process of preparing the doped monocrystal silicon by the seed crystal Czochralski method, the seed crystal is immerged in the molten silicon, the silicon-series material part is molten so that the hole in the seed crystal is opened, so the additive is mixed with the molten silicon.

Preferably, the hole is positioned in a lower portion of the seed crystal. Thus, mixing of the additive and the molten silicon can be achieved only by immerging the lower portion of the seed crystal into the molten silicon.

Preferably, the seed crystal includes multiple holes, the multiple holes are interval-arranged in the seed crystal along a length direction thereof. Thus, it can be guaranteed that the additive is uniformly mixed with the molten silicon.

Preferably, the seed crystal includes 1-6 holes. Thus, it can be guaranteed that the additive is uniformly mixed with the molten silicon.

Preferably, a diameter of the hole is 8-15 millimeters. Thus, it can be guaranteed that the additive is uniformly mixed with the molten silicon.

Preferably, a depth of the hole is 8-15 millimeters. Thus, it can be guaranteed that the additive is uniformly mixed with the molten silicon.

Preferably, a distance between the adjacent two holes is 10-20 millimeters. Thus, it can be guaranteed that the additive is uniformly mixed with the molten silicon.

Preferably, a seed crystal area between the adjacent two holes is a slender neck. Thus, a position can be conveniently identified by an operator.

Preferably, the hole is provided with a thread. Thus, the hole can be conveniently closed.

Preferably, the silicon-series material part is a siliceous bolt, and the siliceous bolt is matched with the thread. Thus, the hole can be conveniently filled.

Preferably, the additives are solid and powder substances.

Preferably, the additives are at least one of a group consisted of a silicon-series master alloy, an Ill-group element dopant, a V-group element dopant, a quartz modifier, a silicide and a nitride. Thus, combination properties of the monocrystal silicon can be remarkably improved.

Preferably, the Ill-group element dopant is at least one of a group consisted of pure boron, pure aluminum, pure gallium, pure indium and pure thallium or at least one of silicide compounds or oxide compounds of boron, aluminum, gallium, indium, thallium. Thus, the combination properties of the monocrystal silicon can be remarkably improved.

Preferably, the V-group element dopant is at least one of a group consisted of pure arsenic, pure phosphorus, pure antimony and pure bismuth or at least one of silicide compounds or oxide compounds of arsenic, phosphorus, antimony, bismuth. Thus, the combination properties of the monocrystal silicon can be remarkably improved.

Preferably, the quartz modifier is at least one of compounds of strontium or barium. Thus, the combination properties of the monocrystal silicon can be remarkably improved.

Preferably, the nitride is a silicon nitride. Thus, the combination properties of the monocrystal silicon can be remarkably improved.

In another aspect of the present disclosure, the present disclosure provides a method for preparing monocrystal silicon by a Czochralski method. According to an embodiment of the present disclosure, the method comprises:

(1) enabling a polysilicon raw material to be molten, so as to obtain molten silicon;

(2) enabling the above seed crystal to be immerged in the molten silicon and stewing; and

(3) operating the seed crystal by the Czochralski method so that the molten silicon grows a crystal, so as to obtain the monocrystal silicon

According to the method for preparing the monocrystal silicon by the Czochralski method of the embodiment of the present disclosure, through using the above seed crystal provided with a hole in which the additive can be stored, the seed crystal is immersed in the molten silicon during a process of preparing the monocrystal silicon by the Czochralski method, the additive in the hole is mixed with the molten silicon, and then the seed crystal is operated by the Czochralski method to prepare doped monocrystal silicon. Compared with an existing mode of adding the additive by using the external or internal quartz tube, it can be guaranteed that the additive is completely added into the molten silicon by using the method of the present application, not only the problems that the additives are stuck to the wall of the quartz tube and the additive is taken away by the argon gas in the furnace so that the product yield is too low are effectively avoided, but also the probability of arcing at the electrode feet is reduced for the down-pumped crystal growth furnace, times of charging and extracting the argon gas are reduced at the same time, and the production time is saved. At the same time, the above seed crystal of the present application is used, the hole and the seed crystal are integrally formed, herein not only the additive is not easy to fall so as to avoid causing the loss of the additives, but also the additive does not fall in advance and is molten within a specified time, for crystal growth of CCZ and RCZ, growth time can be accurately controlled, and production efficiency is improved.

Preferably, in the step (2), all portions, provided with the holes, of the seed crystal are immerged in the molten silicon. Thus, it can be guaranteed that the additive is completely mixed with the molten silicon.

Preferably, in the step (2), time of the stewing is 1-10 minutes. Thus, it can be guaranteed that the additive is completely mixed with the molten silicon.

In a third aspect of the present disclosure, the present disclosure provides monocrystal silicon. According to an embodiment of the present disclosure, the monocrystal silicon is prepared by using the above method. Thus, doped element concentration of the monocrystal silicon is accurate, so that it has excellent performance.

Additional aspects and advantages of the present disclosure are given in the following description, and a part becomes apparent from the following description, or is learned through practice of the present disclosure.

### BRIEF DESCRIPTION OF THE DRAWINGS

The above and/or additional aspects and advantages of the present disclosure become apparent and are easily understood from description of embodiments in combination with the following drawings, it is to be noted that:

FIG. 1 is a structure schematic diagram of a seed crystal according to an embodiment of the present disclosure;

FIG. 2 is a structure schematic diagram of the seed crystal according to another embodiment of the present disclosure;

FIG. 3 is a structure schematic diagram of the seed crystal according to another embodiment of the present disclosure;

FIG. 4 is a structure schematic diagram of the seed crystal according to another embodiment of the present disclosure; and

FIG. 5 is a process schematic diagram of a method for preparing monocrystal silicon by a Czochralski method according to an embodiment of the present disclosure.

### DETAILED DESCRIPTION OF THE EMBODIMENTS

Embodiments of the present disclosure are described in detail below, examples of the embodiments are shown in the drawings, herein the same or similar reference numbers represent the same or similar elements or elements having the same or similar functions from beginning to end. The embodiments described below with reference to the drawings are exemplary, and are intended to explain the present disclosure, but not understood as limitation to the present disclosure.

In the description of the present disclosure, it should be understood that an orientation or position relationship indicated by terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential” and the like is based on the orientation or position relationship shown in the drawings, it is only used to conveniently describe the present disclosure and simplify the description, but not to indicate or imply that a device or element referred must have a specific orientation, and be constructed and operated in the specific orientation, thus it cannot be understood as limitation to the present disclosure.

In the present disclosure, unless specifically stated and defined otherwise, a first feature “above” or “below” a second feature can be direct contact of the first and second features, or indirect contact of the first and second features through an intermediate medium. In addition, the first feature “above”, “on” and “up” the second feature can be that the first feature is directly above or slantwise above the second feature, or it just simply means that a horizontal height of the first feature is greater than that of the second feature. The first feature “below”, “under” and “down” the second feature can be that the first feature is directly below or slantwise below the second feature, or it just simply means that the horizontal height of the first feature is less than that of the second feature.

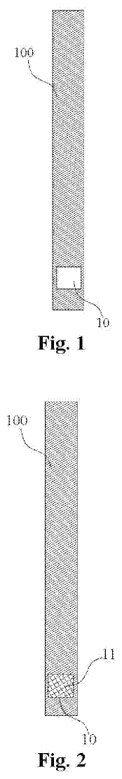

In one aspect of the present disclosure, the present disclosure provides a seed crystal. According to an embodiment of the present disclosure, reference to FIG. 1, the seed crystal 100 is provided with a hole 10, and additive can be stored in the hole 10. It is discovered by the inventor that, through installing the hole in the seed crystal, the hole can store the additive, the seed crystal is immersed in the molten silicon during a process of preparing the monocrystal silicon by a Czochralski method, the additive filled in the hole is mixed with the molten silicon, and then the seed crystal is operated by the Czochralski method to prepare doped monocrystal silicon. Compared with an existing mode of adding the additives by using the external or internal quartz tube, it can be guaranteed that the additive is completely added into the molten silicon by using the seed crystal of the present application, not only the problems that the additive is stuck to the wall of the quartz tube and the additive is taken away by the argon gas in the furnace so that the product yield is too low are effectively avoided, but also the probability of arcing at the electrode feet is reduced for the down-pumped crystal growth furnace, times of charging and extracting the argon gas are reduced at the same time, and the production time is saved. At the same time, the seed crystal of the present application is used, the hole and the seed crystal are integrally formed, herein not only the additive is not easy to fall so as to avoid causing the loss of the additives, but also the additive does not fall in advance and is molten within a specified time, for crystal growth of CCZ and RCZ, growth time can be accurately controlled, and production efficiency is improved.

According to an embodiment of the present disclosure, reference to FIG. 2, the hole 10 is filled by using a silicon-series material part 11. Specifically, the silicon-series material part is molten in a high temperature of the molten silicon while contacting with the molten silicon, thereby the hole is opened, so that the additive stored in the hole is mixed with the molten silicon. According to a specific embodiment of the present disclosure, the additive can be solid and powder substances, thus it is charged in the hole in the seed crystal so that the additive can be prevented from leaking. Specifically, the additive is at least one of a group consisted of a silicon-series master alloy, an Ill-group element dopant, a V-group element dopant, a quartz modifier, a silicide and a nitride, herein, the Ill-group element dopant is at least one of a group consisted of pure boron, pure aluminum, pure gallium, pure indium and pure thallium or at least one of silicide compounds or oxide compounds of boron, aluminum, gallium, indium, thallium, the V-group element dopant is at least one of a group consisted of pure arsenic, pure phosphorus, pure antimony and pure bismuth or at least one of silicide compounds or oxide compounds of arsenic, phosphorus, antimony, bismuth, the quartz modifier is at least one of compounds of strontium or barium, the nitride is a silicon nitride. It is to be noted that the additive can be selected by those skilled in the art according to the needs of monocrystal silicon properties. Such a filling mode can be used to effectively avoid a problem that the additive is rolled or blown away so that the product yield is excessive low, and the probability of arcing at the electrode feet is reduced for the down-pumped crystal growth furnace, times of charging and extracting the argon gas are reduced at the same time, and the production time is saved.

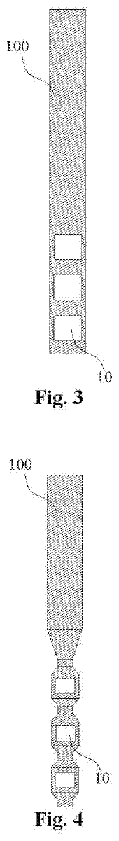

According to another embodiment of the present disclosure, reference to FIG. 1, the hole 10 is positioned in a lower portion of the seed crystal 100. Thus, in a process of adding the additive, only the lower portion of the seed crystal is immerged in the molten silicon so that mixing of the additive and the molten silicon can be achieved. Preferably, reference to FIG. 3, the seed crystal 100 can be provided with multiple holes 10, and the multiple holes 10 are interval-arranged in the seed crystal 100 along a length direction thereof, for example, uniform interval-arrangement. It is to be noted that the same kind of dopant or the different kinds of dopant can be placed in the multiple holes 10, it can be selected by those skilled in the art according to the actual needs. The seed crystal of the present application can be repeatedly used, one seed crystal can perform multiple times of doping of the additive, the additive do not need to be re-prepared during every time of doping, time and cost are saved.

According to another embodiment of the present disclosure, the seed crystal 100 can be provided with 1-6 holes, it can be selected by those skilled in the art according to the actual needs, for example, 1 hole, 2 holes, 3 holes, 4 holes, 5 holes or 6 holes are installed, and a diameter of each hole is 8-15 millimeters, and a depth is 8-15 millimeters.

According to another embodiment of the present disclosure, reference to FIG. 3, a distance between the adjacent two holes 10 is 10-20 millimeters. It is discovered by the inventor that such a distance range can be used to avoid the seed crystal from cracking during processing, and a silicon material is saved. For example, the distance between the adjacent two holes 10 can be 10 millimeters, 11 millimeters, 12 millimeters, 13 millimeters, 14 millimeters, 15 millimeters, 16 millimeters, 17 millimeters, 18 millimeters, 19 millimeters and 20 millimeters.

According to another embodiment of the present disclosure, in order to conveniently identify a position of the hole by an operator and guarantee that the hole is completely immerged in the molten silicon, reference to FIG. 4, a seed crystal 100 area between the adjacent two holes 10 is used as a slender neck, namely a diameter of the seed crystal in the slender neck area is less than a diameter of the seed crystal in other portions.

According to another embodiment of the present disclosure, the hole 10 can be provided with a thread, the silicon-series material part 11 can be a siliceous bolt, the siliceous bolt is matched with the thread in the hole. Thus, after the hole is filled with the additives, the siliceous bolt is used to match with the thread so that filling of the hole can be achieved, and the additive is avoided from leaking, and while the additive is required to be added, a part, provided with the hole, of the seed crystal is immerged in the molten silicon, the siliceous bolt is molten under the effect of the high-temperature molten silicon, thereby the hole is opened, so that the additive in the hole is mixed with the molten silicon.

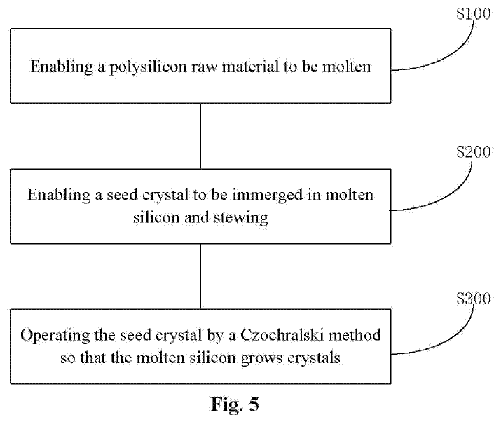

In another aspect of the present disclosure, the present disclosure provides a method for preparing monocrystal silicon by a Czochralski method. According to an embodiment of the present disclosure, reference to FIG. 5, the method comprises:

S100: enabling a polysilicon raw material to be molten.

In this step, the polysilicon raw material is heated in a quartz crucible and completely molten, to obtain molten silicon.

S200: enabling the seed crystal to be immerged in the molten silicon and stewing.

In this step, the above seed crystal provided with the hole in which the additive is stored is fixed on a seed crystal clamping head, and then a lower part of the seed crystal is immerged in the molten silicon and stewing, in a high temperature of the molten silicon, the silicon-series material part in the hole is molten so that the hole is opened, thereby the additive in the hole is mixed with the molten silicon. Preferably, all portions, provided with the holes, of the seed crystal are immerged in the molten silicon, thereby it is guaranteed that the additive is completely mixed with the molten silicon. According to a specific embodiment of the present disclosure, time of the stewing can be 1-10 minutes, thereby it is guaranteed that the dopant is uniformly mixed with the molten silicon. For example, the stewing time is 1 minute, 2 minutes, 3 minutes, 4 minutes, 5 minutes, 6 minutes, 7 minutes, 8 minutes, 9 minutes and 10 minutes.

S300: operating the seed crystal by the Czochralski method so that the molten silicon grows crystals.

In the step, the seed crystal clamping head is used to operate the seed crystal into the molten silicon to grow crystal by the Czochralski method, and through necking, shouldering and body growing phases, the monocrystal silicon is obtained. It is to be noted that a process of operating the seed crystal by the Czochralski method is normal operation in the present field, it is not specifically elaborated here.

According to the method for preparing the monocrystal silicon by the Czochralski method of the embodiment of the present disclosure, through using the above seed crystal provided with the hole in which the additive can be stored, the seed crystal is immersed in the molten silicon during a process of preparing the monocrystal silicon by the Czochralski method, the additive in the hole is mixed with the molten silicon, and then the seed crystal is operated by the Czochralski method to prepare doped monocrystal silicon. Compared with an existing mode of adding the additive by using the external or internal quartz tube, it can be guaranteed that the additive is completely added into the molten silicon by using the method of the present application, not only the problems that the additive is stuck to the wall of the quartz tube and the additive is taken away by the argon gas in the furnace so that the product yield is too low are effectively avoided, but also the probability of arcing at the electrode feet is reduced for the down-pumped crystal growth furnace, times of charging and extracting the argon gas are reduced at the same time, and the production time is saved. At the same time, the above seed crystal of the present application is used, the hole and the seed crystal are integrally formed, herein not only the additive is not easy to fall so as to avoid causing the loss of the additive, but also the additive does not fall in advance and is molten within a specified time, for crystal growth of CCZ and RCZ, growth time can be accurately controlled, and production efficiency is improved. It is to be noted that the above features and advantages described in allusion to the seed crystal are also suitable for the method for preparing the monocrystal silicon by the Czochralski method, it is not repeatedly described here.

In a third aspect of the present disclosure, the present disclosure provides a monocrystal silicon. According to an embodiment of the present disclosure, the monocrystal silicon is prepared by using the above method. Thus, doped element concentration of the monocrystal silicon is accurate, so it has excellent performance. It is to be noted that the above features and advantages described in allusion to the method for preparing the monocrystal silicon by the Czochralski method are also suitable for the monocrystal silicon, it is not repeatedly described here.

The present disclosure is described below with reference to the specific embodiments, it is to be noted that these embodiments are only descriptive and do not limit the present disclosure in any modes.

### Embodiment 1

(1) A polysilicon raw material was molten, so as to obtain molten silicon;

(2) a seed crystal was immerged in the molten silicon and stewing for 1 minute, herein, a lower portion of the seed crystal was provided with 6 holes, a B—Si master alloy was stored in all of the 6 holes, and the holes were filled by using a siliceous bolt, a distance between the adjacent holes was 10 millimeters; and

(3) the seed crystal was operated to grow crystal by a Czochralski method, so as to obtain boron-doped monocrystal silicon.

### Embodiment 2

(1) A polysilicon raw material was molten, so as to obtain molten silicon;

(2) a seed crystal was immerged in the molten silicon and stewing for 2 minute, herein, a lower portion of the seed crystal was provided with 1 hole, a P—Si dopant was stored in the hole, and the hole was filled by using a siliceous bolt; and

(3) the seed crystal was operated to grow crystal by a Czochralski method, so as to obtain phosphorus-doped monocrystal silicon.

### Embodiment 3

(1) A polysilicon raw material was molten, so as to obtain molten silicon;

(2) a seed crystal was immerged in the molten silicon and stewing for 8 minute, herein, a lower portion of the seed crystal was provided with 4 holes, a pure antimony dopant was stored in all of the 4 holes, and the holes were filled by using a siliceous bolt, a distance between the adjacent holes was 16 millimeters; and

(3) the seed crystal was operated to grow crystal by a Czochralski method, so as to obtain antimony-doped monocrystal silicon.

### Embodiment 4

(1) A polysilicon raw material was molten, so as to obtain molten silicon;

(2) a seed crystal was immerged in the molten silicon and stewing for 6 minutes, herein, a lower portion of the seed crystal was provided with 3 holes, a pure boron dopant was stored in all of the 3 holes, and the holes were filled by using a siliceous bolt, a distance between the adjacent holes was 14 millimeters; and

(3) the seed crystal was operated to grow crystal by a Czochralski method, so as to obtain boron-doped monocrystal silicon.

### Embodiment 5

(1) A polysilicon raw material was molten, so as to obtain molten silicon;

(2) a seed crystal was immerged in the molten silicon and stewing for 10 minutes, herein, a lower portion of the seed crystal was provided with 5 holes, a quartz modifier (barium carbonate BaCO3) dopant was stored in all of the 5 holes and the holes were filled by using a siliceous bolt, a distance between the adjacent holes was 20 millimeters; and

(3) the seed crystal was operated to grow crystal by a Czochralski method, so as to obtain doped monocrystal silicon.

### Comparative Embodiment 1

(1) A polysilicon raw material was molten, so as to obtain molten silicon;

(2) a B—Si master alloy was added to the molten silicon through a quartz tube; and

(3) the seed crystal was operated to grow crystal by a Czochralski method, so as to obtain boron-doped monocrystal silicon.

### Comparative Embodiment 2

(1) A polysilicon raw material was molten, so as to obtain molten silicon;

(2) a P—Si dopant was added to the molten silicon; and

(3) the seed crystal was operated to grow crystal by a Czochralski method, so as to obtain phosphorus-doped monocrystal silicon.

### Comparative Embodiment 3

(1) A polysilicon raw material was molten, so as to obtain molten silicon;

(2) a pure antimony dopant was added to the molten silicon through a quartz tube; and

(3) the seed crystal was operated to grow crystal by a Czochralski method, so as to obtain antimony-doped monocrystal silicon.

### Comparative Embodiment 4

(1) A polysilicon raw material was molten, so as to obtain molten silicon;

(2) a pure boron dopant was added to the molten silicon through a quartz tube; and

(3) the seed crystal was operated to grow crystal by a Czochralski method, so as to obtain boron-doped monocrystal silicon.

### Comparative Embodiment 5

(1) A polysilicon raw material was molten, so as to obtain molten silicon;

(2) a quartz modifier (barium carbonate BaCO3) dopant was added to the molten silicon through a quartz tube; and

(3) the seed crystal was operated to grow crystal by a Czochralski method, so as to obtain doped monocrystal silicon.

Evaluation:

The abnormal rate of top resistivity and the arcing percentage (arcing) of the monocrystal silicon obtained in Embodiments 1-5 and Comparative Embodiments 1-5 are evaluated respectively. Herein:

The top resistivity is measured by four-point probe, referring to GB/T 1551-2009 Test method for measuring resistivity of monocrystal silicon, which is normal within +1-5% of a target resistivity value, otherwise is abnormal.

The arcing percentage refers to the probability of heater arcing in one hundred furnaces.

TABLE 1
Comparison of monocrystal silicon obtained in
Embodiments 1-5 and Comparative Embodiments 1-5

| | The abnormal rate of | The Arcing |
|---|---|---|
| | top resistivity | percentage |
| Embodiment 1 | 0.53% | — |
| Embodiment 2 | 0% | — |
| Embodiment 3 | 0.79% | — |
| Embodiment 4 | 0.625% | — |
| Embodiment 5 | — | 0% |
| Comparative | 1.09% | — |
| Embodiment 1 | | |
| Comparative | 1.63% | — |
| Embodiment 2 | | |
| Comparative | 0.97% | — |
| Embodiment 3 | | |
| Comparative | 1.16% | — |
| Embodiment 4 | | |
| Comparative | — | 48% |
| Embodiment 5 | | |

In the description of the present description, the description referring to terms “one embodiment”, “some embodiments”, “example”, “specific examples”, or “some examples” and the like means that specific features, structures, materials or characteristics described in combination with the embodiment or the example are included in at least one embodiment or example of the present disclosure. In the present description, the schematic expression of the above terms does not necessarily refer to the same embodiment or example. In addition, the specific features, structures, materials or characteristics described can be combined in any one or more embodiments or examples in suitable modes. Furthermore, in the case without mutual contradiction, the different embodiments or examples and the features of the different embodiments or examples described in the present description can be incorporated and combined by those skilled in the art.

Although the embodiments of the present disclosure are shown and described above, it should be understood that the above embodiments are exemplary, and it can not be understood as limitation to the present disclosure. Changes, corrections, replacements and modifications can be made to the above embodiments within a scope of the present disclosure by those of ordinary skill in the art.

1. A seed crystal, the seed crystal is provided with a hole, and additive can be stored in the hole.

2. The seed crystal according to claim 1, wherein the hole is filled by a silicon-series material part.

3. The seed crystal according to claim 1, wherein the hole is positioned in a lower portion of the seed crystal.

4. The seed crystal according to claim 1, wherein the seed crystal comprises multiple holes, the multiple holes are interval-arranged in the seed crystal along a length direction thereof.

5. The seed crystal according to claim 1, wherein the seed crystal comprises 1-6 holes.

6. The seed crystal according to claim 1, wherein a diameter of the hole is 8-15 millimeters.

7. The seed crystal according to claim 1, wherein a depth of the hole is 8-15 millimeters.

8. The seed crystal according to claim 1, wherein a distance between the adjacent two holes is 10-20 millimeters.

9. The seed crystal according to claim 1, wherein a seed crystal area between the adjacent two holes is a slender neck.

10. The seed crystal according to claim 1, wherein the hole is provided with a thread.

11. The seed crystal according to claim 1, wherein the silicon-series material part is a siliceous bolt, and the siliceous bolt is matched with the thread.

12. The seed crystal according to claim 1, wherein the additive is solid substance and powder substance.

13. The seed crystal according to claim 1, wherein the additive is at least one of a group consisted of a silicon-series master alloy, a III-group element dopant, a V-group element dopant, a quartz modifier, a silicide and a nitride.

14. The seed crystal according to claim 13, wherein the III-group element dopant is at least one of a group consisted of pure boron, pure aluminum, pure gallium, pure indium and pure thallium or at least one of silicide compounds or oxide compounds of boron, aluminum, gallium, indium, thallium, or
the V-group element dopant is at least one of a group consisted of pure arsenic, pure phosphorus, pure antimony and pure bismuth or at least one of silicide compounds or oxide compounds of arsenic, phosphorus, antimony, bismuth.

15. (canceled)

16. The seed crystal according to claim 13, wherein the quartz modifier is at least one of compounds of strontium or barium.

17. The seed crystal according to claim 13, wherein the nitride is a silicon nitride.

18. A method for preparing monocrystal silicon by a Czochralski method, comprising:
(1) enabling a polysilicon raw material to be molten, so as to obtain molten silicon;
(2) enabling the seed crystal as claimed in claim 1 to be immerged in the molten silicon and stewing; and
(3) operating the seed crystal by the Czochralski method so that the molten silicon grows a crystal, so as to obtain the monocrystal silicon.

19. The method according to claim 18, wherein in the step (2), all portions, provided with holes, of the seed crystal are immerged in the molten silicon.

20. The method as according to claim 18, wherein in the step (2), a time of the stewing is 1-10 minutes.

21. A monocrystal silicon, wherein the monocrystal silicon is prepared by using the method as claimed in claim 18.
